(19) United States
(12) Patent Application Publication
(10) Pub. No.: US 2026/0107615 A1
(43) Pub. Date: Apr. 16, 2026

(54) ELECTRONIC DEVICE

(71) Applicant: CARUX TECHNOLOGY PTE. LTD., SINGAPORE (SG)

(72) Inventors: Szu-Yen Yu, Tainan (TW); Yu-Hsuan Hsiao, Tainan (TW); Yen-Liang Chen, Tainan (TW); Fang-Ho Lin, Tainan (TW)

(73) Assignee: CARUX TECHNOLOGY PTE. LTD., SINGAPORE (SG)

(21) Appl. No.: 19/325,503

(22) Filed: Sep. 11, 2025

(30) Foreign Application Priority Data
Oct. 14, 2024 (CN) 202411431677.0

(51) Int. Cl. H10H 29/85; H10H 29/24; H10H 29/855

(52) U.S. Cl. CPC H10H 29/8506; H10H 29/24; H10H 29/855

(57) ABSTRACT

An electronic device includes a substrate, multiple light-emitting elements, and multiple barrier walls. The light-emitting elements are arranged in an array on the substrate. The barrier walls are disposed on the substrate and surround the light-emitting elements, wherein the barrier walls include multiple first barrier walls extending along a first direction and multiple second barrier walls extending along a second direction. In a top view of the electronic device, at least one of the multiple first barrier walls and at least one of the multiple second barrier walls surround one of the multiple light-emitting elements, and the terminal end of at least one of multiple first barrier walls is adjacent to and spaced apart by a distance from the terminal end of at least one of the multiple second barrier walls. The electronic device provided herein may possess relatively good display quality and/or relatively low manufacturing costs.

### CROSS-REFERENCE TO RELATED APPLICATION

This application claims the priority benefit of China application serial no. 202411431677.0, filed on October 14, 2024. The entirety of the above-mentioned patent application is hereby incorporated by reference herein and made a part of this specification.

### BACKGROUND

### FIELD OF THE DISCLOSURE

This disclosure pertains to an electronic device, specifically relating to an electronic device including chip-scale package light-emitting diodes.

### DESCRIPTION OF RELATED ART

In the existing technology of light emitting diodes (LEDs), a barrier wall is typically utilized to guide the light emitted from the LED towards the upper direction for light output. However, the current design of the barrier wall tends to exhibit traces of a grid pattern, which adversely affects the display quality of the electronic device. Consequently, the phenomenon results in the electronic device having relatively poor light output efficiency and/or display quality.

### SUMMARY OF THE DISCLOSURE

Some embodiments disclosed herein pertain to an electronic device that may possess relatively improved display quality.

According to some embodiments disclosed herein, an electronic device is provided, including a substrate, a plurality of light-emitting elements, and a plurality of barrier walls. The plurality of light-emitting elements are arranged in an array on the substrate. The plurality of barrier walls are disposed on the substrate and surround the plurality of light-emitting elements, wherein the plurality of barrier walls include a plurality of first barrier walls extending along a first direction and a plurality of second barrier walls extending along a second direction, and the first direction is perpendicular to the second direction. In a top view of the electronic device, at least one of the plurality of first barrier walls and at least one of the plurality of second barrier walls surround one of the plurality of light-emitting elements, and a terminal end of at least one of the plurality of first barrier walls is proximate to and spaced apart by a distance from a terminal end of at least one of the plurality of second barrier walls.

According to some other embodiments disclosed herein, an electronic device is provided, including a substrate, a plurality of light-emitting elements, and a plurality of barrier walls. The plurality of light-emitting elements are arranged in an array on the substrate. The plurality of barrier walls are disposed on the substrate and surround the plurality of light-emitting elements, wherein the plurality of barrier walls include a plurality of first barrier walls extending along a first direction and a plurality of second barrier walls extending along a second direction, and the first direction is perpendicular to the second direction. In a top view of the electronic device, at least one of the plurality of first barrier walls and at least one of the plurality of second barrier walls surround one of the plurality of light-emitting elements, and at least one of the plurality of first barrier walls is connected to the at least one of the plurality of second barrier walls, and at least one of the plurality of first barrier walls has an opening.

Based on the foregoing, the electronic device provided in this disclosure incorporates a design featuring a plurality of barrier walls, including non-continuous barrier walls. This configuration allows light emitted from adjacent light-emitting units to mix through the opening between the non-continuous barrier walls, thereby enhancing the uniformity of light output. Consequently, this design improves the display quality of the electronic device. Furthermore, the electronic device disclosed herein may be constructed without the inclusion of light-homogenizing films, high-haze diffusion plates, or similar layered components, thus resulting in comparatively lower manufacturing costs.

In order to make the above features and advantages of the present disclosure more obvious and understandable, embodiments are given below with reference to the accompanying drawings for detailed description as follows.

### BRIEF DESCRIPTION OF THE DRAWINGS

FIG. 1A is a partial top view of an electronic device according to the first embodiment of the present disclosure.

FIG. 1B is a partial top view of an electronic device according to the second embodiment of the present disclosure.

FIG. 1C is a partial top view of an electronic device according to the third embodiment of the present disclosure.

FIG. 1D is a partial top view of an electronic device according to the fourth embodiment of the present disclosure.

FIG. 2A is a partial cross-sectional view of an electronic device according to the fifth embodiment of the present disclosure.

FIG. 2B is a partial cross-sectional view of an electronic device according to the sixth embodiment of the present disclosure.

FIG. 3A is a flow chart illustrating a manufacturing method of an electronic device according to the seventh embodiment of the present disclosure.

FIG. 3B is a partial cross-sectional view of an embodiment of the manufacturing method of the electronic device depicted in FIG. 3A.

FIG. 3C is a flow chart illustrating a manufacturing method of an electronic device according to the eighth embodiment of the present disclosure.

FIG. 3D is a flow chart illustrating a manufacturing method of an electronic device according to the ninth embodiment of the present disclosure.

FIG. 3E is a flow chart illustrating a manufacturing method of an electronic device according to the tenth embodiment of the present disclosure.

FIG. 4A is a partial cross-sectional view of an electronic device according to the eleventh embodiment of the present disclosure.

FIG. 4B is a partial cross-sectional view of an electronic device according to the twelfth embodiment of the present disclosure.

FIG. 4C is a partial cross-sectional view of an electronic device according to the thirteenth embodiment of the present disclosure.

### DESCRIPTION OF EMBODIMENTS

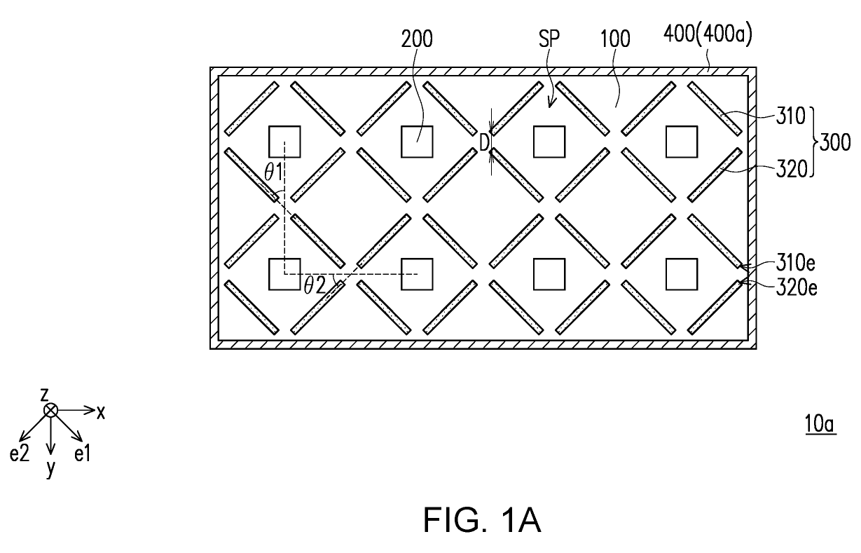

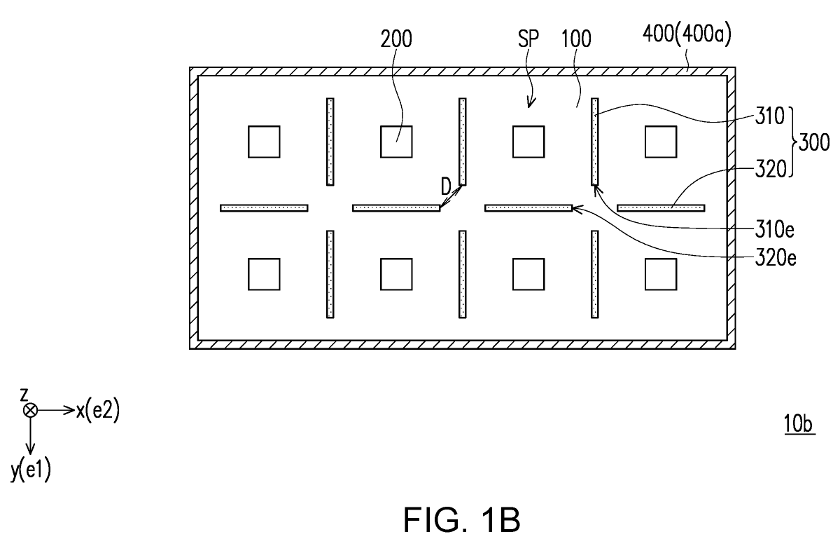

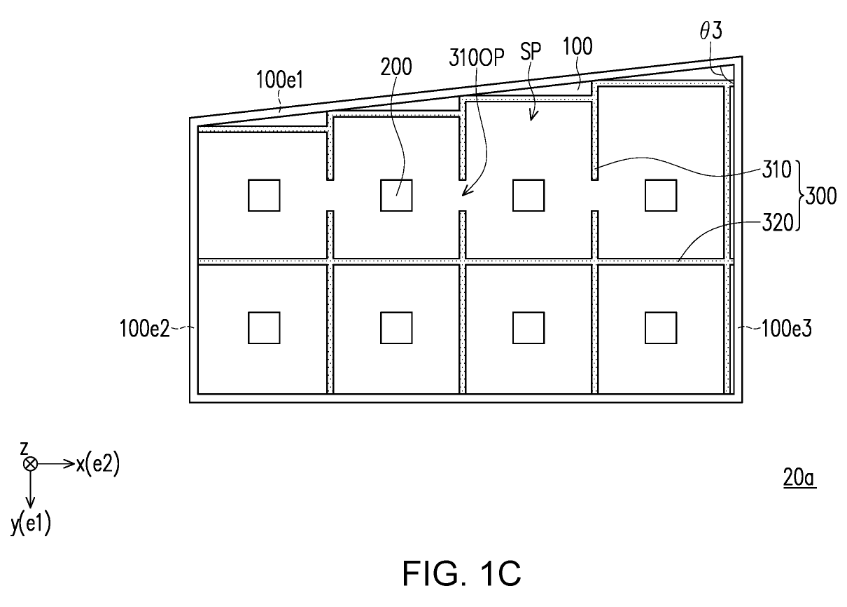

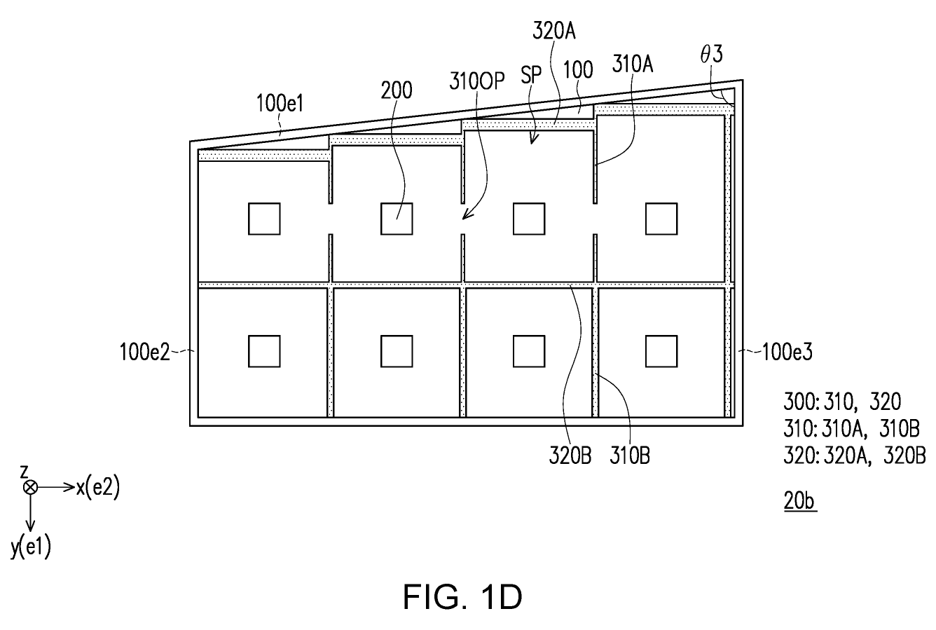

FIG. 1A is a partial top view of an electronic device according to the first embodiment of the present disclosure.

Please refer to FIG. 1A. In this embodiment, the electronic device 10a includes a substrate 100, a plurality of light-emitting elements 200, and a plurality of barrier walls 300.

The substrate 100 may be utilized to support elements and layered components positioned thereon. The substrate 100 may include glass, quartz, sapphire, ceramic, polyimide (PI), polycarbonate (PC), polyethylene terephthalate (PET), other suitable materials, or combinations thereof. Furthermore, in some embodiments, the substrate 100 may incorporate circuit structures (not shown) to drive a plurality of light-emitting elements 200 disposed thereon.

A plurality of light-emitting elements 200 are, for example, arranged in an array on the substrate 100. In some embodiments, the plurality of light-emitting elements 200 may be four-sided emitting mini LEDs. Specifically, the plurality of light-emitting elements 200 may emit light in directions (e.g., direction x and direction y and their opposite directions) perpendicular to the top view direction z of the electronic device 10a, but the present disclosure is not limited thereto. In other embodiments, the plurality of light-emitting elements 200 may be five-sided emitting mini LEDs.

The plurality of barrier walls 300 is, for example, disposed on the substrate 100 and arranged surrounding the plurality of light-emitting elements 200. In some embodiments, the plurality of barrier walls 300 may be utilized to define the placement positions of the plurality of light-emitting elements 200; however, the present disclosure is not limited thereto. The plurality of barrier walls 300 includes, for example, materials with high reflectivity. By way of example, the material of the plurality of barrier walls 300 may include silica gel; however, the present disclosure is not limited thereto. Through the arrangement of the plurality of barrier walls 300, the light emitted from the plurality of light-emitting elements 200 may be reflected multiple times by the plurality of barrier walls 300 and subsequently transformed to emit light in a collimated direction (opposite to the top view direction z of the electronic device 10a), thereby enhancing the light output brightness of the electronic device 10a. In some embodiments, the height of the plurality of barrier walls 300 may range from 0.2 millimeters to 5 millimeters.

In the present embodiment, the plurality of barrier walls 300 includes a plurality of first barrier walls 310 extending along a direction e1 and a plurality of second barrier walls 320 extending along a direction e2. The direction e1 is, for example, perpendicular to the direction e2, and both the direction e1 and the direction e2 are, for example, perpendicular to the top view direction z of the electronic device 10a. In some embodiments, when viewed from the top view direction z of the electronic device 10a, at least one of the plurality of first barrier walls 310 and at least one of the plurality of second barrier walls 320 are arranged surrounding one of the plurality of light-emitting elements 200, and the terminal end 310e of at least one of the plurality of first barrier walls 310 is proximate to and spaced apart by a distance D from the terminal end 320e of at least one of the plurality of second barrier walls 320. Specifically, in this embodiment, the plurality of first barrier walls 310 and the plurality of second barrier walls 320 are independently arranged in a non-continuous manner respectively, such that the space SP enclosed by the corresponding two first barrier walls 310 and the corresponding two second barrier walls 320 has an opening. Based on this configuration, the arrangement of the plurality of barrier walls 300 in this embodiment may enhance the light-mixing effect of the light emitted by the plurality of light-emitting elements 200, thereby improving the light output uniformity of the electronic device 10a.

In this embodiment, the row alignment direction (direction y) of the plurality of light-emitting elements 200 forms an angle Ө1 of 40° to 50° with the extension direction e1 of the plurality of first barrier walls 310, and the column alignment direction (direction x) of the plurality of light-emitting elements 200 forms an angle Ө2 of 40° to 50° with the extension direction e2 of the plurality of second barrier walls 320. When the plurality of light-emitting elements 200 are sub-millimeter light-emitting diodes with four-sided emission, they exhibit relatively high light output intensity in the directions e1, e2, and their opposite directions. Therefore, the light output intensity of light emitted in the collimated direction (the opposite direction of the top view direction z of the electronic device 10a) of the electronic device 10a may be enhanced by designing the angle between the alignment direction of the plurality of light-emitting elements 200 and the extension direction of the plurality of barrier walls 300 to conform to the aforementioned relationship.

In the present embodiment, the electronic device 10a further includes a back plate 400. The back plate 400 is, for example, disposed on one side of the substrate 100 away from the plurality of light-emitting elements 200. The back plate 400 includes, for instance, an outer frame portion 400a, wherein the outer frame portion 400a is, for example, disposed at the periphery of the electronic device 10a to form a space accommodating at least one substrate 100, but the present disclosure is not limited thereto. The back plate 400 may, for example, include materials with high heat dissipation properties. By way of illustration, the material of the back plate 400 may include aluminum, but the present disclosure is not limited thereto.

In this embodiment, the electronic device 10a further includes a reflective layer (not shown). The reflective layer is, for example, disposed on the substrate 100 and surrounds the plurality of light-emitting elements 200, for example. Specifically, the reflective layer may, for instance, cover at least a portion of the sidewalls of the plurality of light-emitting elements 200, but does not cover the light-emitting layer (not shown) of the plurality of light-emitting elements 200. A detailed description of the reflective layer will be provided in the following embodiments and will not be elaborated upon here.

Based on the foregoing, in this embodiment, the terminal end 310e of at least one of the plurality of first barrier walls 310 in the electronic device 10a is proximate to and spaced apart by a distance D1 from the terminal end 320e of at least one of the plurality of second barrier walls 320. This configuration allows light emitted from adjacent light-emitting units to mix through the opening between the first barrier wall and the second barrier wall, thereby enhancing the light output uniformity of the electronic device 10a. Consequently, this arrangement may reduce the appearance of grid patterns caused by the first barrier walls 310 and/or the second barrier walls 320 during light emission from the electronic device 10a, thus improving the display quality of the electronic device 10a.

FIG. 1B is a partial top view of an electronic device according to the second embodiment of the present disclosure. It should be noted that the embodiment of FIG. 1B may adopt the reference numerals and partial content of the embodiment of FIG. 1A, wherein identical or similar numerals are used to denote identical or similar elements, and explanations of identical technical content are omitted.

Please refer to FIG. 1B. The primary difference between the electronic device 10b in this embodiment and the electronic device 10a is as follows: the row alignment direction (direction y) of the plurality of light-emitting elements 200 is parallel to the extension direction e1 of the plurality of first barrier walls 310. Additionally, the column alignment direction (direction x) of the plurality of light-emitting elements 200 is parallel to the extension direction e2 of the plurality of second barrier walls 320.

FIG. 1C is a partial top view of an electronic device according to the third embodiment of the present disclosure.

Please refer to FIG. 1C. The primary distinction between the electronic device 20a of the present embodiment and the electronic device 10a lies in the following: the substrate 100 has an irregular edge formed at least by edges 100e1, 100e2, and 100e3. Furthermore, a plurality of first barrier walls 310, positioned on one side of the edge 100e1 of the substrate 100, is configured to include an opening 310OP.

In more specific terms, in the present embodiment, the extension direction of the edge 100e1 of the substrate 100 forms a non-90° angle with the extension directions of the adjacently connected edges 100e2 and 100e3. Consequently, the plurality of first barrier walls 310 positioned at one side of the edge 100e1 of the substrate 100 will have varying lengths in the direction y while extending along the direction x. This variation will impact the light output intensity of the respective spaces SP located at one side of the edge 100e1 of the substrate 100.

In the present embodiment, the plurality of light-emitting elements 200 includes light-emitting elements 200 disposed in the outermost column. Due to the relatively inferior light-mixing effect of the light-emitting elements 200 located in the outermost column compared to the remaining light-emitting elements 200, the light-emitting elements 200 in the outermost column are more susceptible to the formation of dark areas as a result of the plurality of first barrier walls 310 having different lengths in the direction y. To address this issue, in the electronic device 20a of the present embodiment, the plurality of first barrier walls 310 disposed on one side of the edge 100e1 of the substrate 100 are configured to have an opening 310OP. The opening 310OP is correspondingly positioned in the direction x with respect to the adjacent light-emitting elements 200. Through the design of this opening 310OP, the light-mixing effect of the light emitted from the light-emitting elements 200 disposed in the outermost column may be enhanced, thereby reducing the occurrence of dark areas and improving the display quality of the electronic device 20a.

Furthermore, in the present embodiment, at least one of the plurality of first barrier walls 310 is connected to at least one of the plurality of second barrier walls 320. The remaining plurality of first barrier walls 310 that are not positioned on one side of the edge 100e1 of the substrate 100 may not have openings 310OP. However, the present disclosure is not limited to this configuration.

FIG. 1D is a partial top view of an electronic device according to the fourth embodiment of the present disclosure.

Please refer to FIG. 1D. The primary difference between the electronic device 20b in this embodiment and the electronic device 20a lies in the following: the height of the second barrier wall 320 surrounding the outermost column of light-emitting elements 200 is greater than the height of the first barrier wall 310.

In more detail, in the present embodiment, the height of the plurality of first barrier walls 310A disposed on one side of the edge 100e1 of the substrate 100 may be lower than the height of the remaining first barrier walls 310B. Additionally, the height of the plurality of second barrier walls 320A disposed on one side of the edge 100e1 of the substrate 100 may be higher than the height of the remaining second barrier walls 320B. Consequently, the height of the second barrier walls 320A surrounding the outermost column of light-emitting elements 200 will be higher than the height of the first barrier walls 310A. In some embodiments, the heights of the first barrier walls 310A, the first barrier walls 310B, the second barrier walls 320A, and the second barrier walls 320B may range from 0.2 millimeters to 5 millimeters.

Through the aforementioned design of the plurality of first barrier walls 310, the plurality of first barrier walls 310 situated on one side of the edge 100e1 of the substrate 100 possess a relatively low height, thereby further enhancing the light-mixing effect of the light emitted by the light-emitting elements 200 located in the outermost column. Furthermore, by virtue of the aforementioned design of the plurality of second barrier walls 320, the number of reflections of light emitted by the light-emitting elements 200 located in the outermost column through the plurality of second barrier walls 320 situated on one side of the edge 100e1 of the substrate 100 may be increased. This serves to confine the light emitted by the light-emitting elements 200 located in the outermost column within a narrower angular range upon emission, thereby enhancing the light output efficiency of the electronic device 20b.

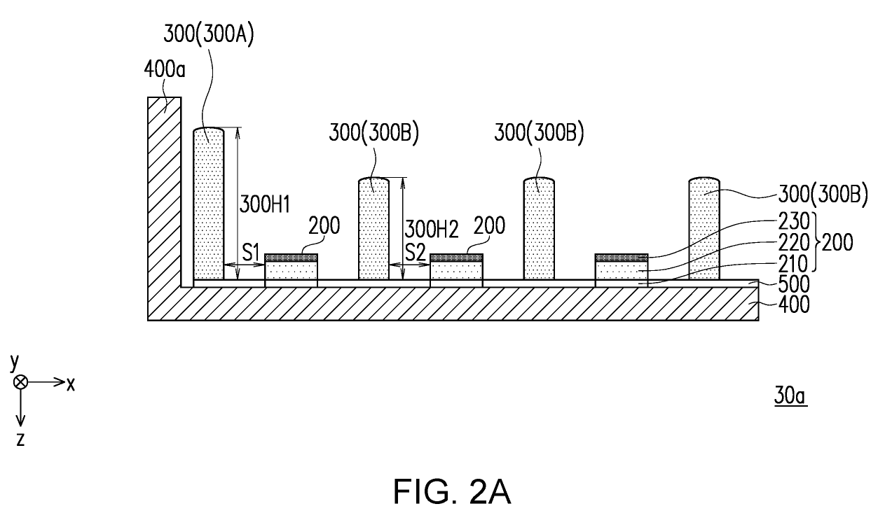

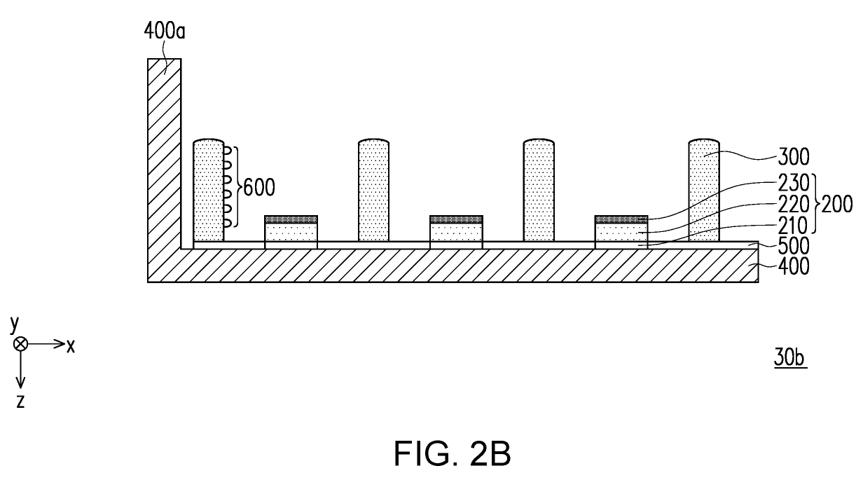

FIG. 2A is a partial cross-sectional view of an electronic device according to the fifth embodiment of the present disclosure. It should be noted that the embodiment of FIG. 2A may adopt the reference numerals and partial content of the embodiment of FIG. 1A.

Please refer to FIG. 2A. The primary distinction between the electronic device 30a in this embodiment and the electronic device 10a lies in the following: the height 300H1 of the barrier wall 300 nearest to the outer frame portion 400a of the back plate 400 is greater than the height 300H2 of the remaining barrier walls 300.

In this embodiment, the reflective layer 500 is, for example, disposed on the substrate 100 and surrounds the plurality of light-emitting elements 200. The reflective layer 500 includes, for example, a material with high reflectivity. By way of illustration, the material of the reflective layer 500 may include silica gel (e.g., white adhesive), but the present disclosure is not limited thereto.

Furthermore, in this embodiment, FIG. 2A illustrates the structure of the light-emitting elements 200. Specifically, the light-emitting elements 200 may include, for example, a base 210, a light-emitting layer 220, and a light-shielding layer 230, wherein the base 210, light-emitting layer 220, and light-shielding layer 230 are sequentially disposed on the back plate 400 in this order. Moreover, the light-shielding layer 230, for instance, covers the top surface of the light-emitting layer 220 to block light emitted from the light-emitting elements 200 in a direction opposite to the top view direction z of the electronic device 30a.

In the present embodiment, the height 300H1 of the barrier wall 300A nearest to the outer frame portion 400a of the back plate 400 is higher than the height 300H2 of the other barrier walls 300B. Consequently, the number of reflections of light emitted by the light-emitting elements 200 through the barrier wall 300A nearest to the outer frame portion 400a is increased. This configuration constrains the light emitted by the light-emitting elements 200 to exit within a narrower angular range, thereby enhancing the light output efficiency of the electronic device 30a.

In some embodiments, the distance S1 between the barrier walls 300A and the light-emitting elements 200 may be equivalent to the distance S2 between the barrier walls 300B and the light-emitting elements 200. In other embodiments, the distance S1 between the barrier walls 300A and the light-emitting elements 200 may differ from the distance S2 between the barrier walls 300B and the light-emitting elements 200. By way of illustration, without limitation, the distance S1 between the barrier walls 300A and the light-emitting elements 200 may be greater than the distance S2 between the barrier walls 300B and the light-emitting elements 200.

FIG. 2B is a partial cross-sectional view of an electronic device according to the sixth embodiment of the present disclosure.

Please refer to FIG. 2B. The primary difference between the electronic device 30b in this embodiment and the electronic device 10a lies in the following: the electronic device 30b additionally includes a light-converging element 600 positioned on the barrier wall 300 that is nearest to the outer frame portion 400a of the back plate 400.

The light-converging element 600 may include, for example, a plurality of lenses, but the present disclosure is not limited thereto. In this embodiment, by positioning the light-converging element 600 on the barrier wall 300 nearest to the outer frame portion 400a of the back plate 400, the light emitted from the light-emitting element 200 nearest to the outer frame portion 400a of the back plate 400 may be refracted by the light-converging element 600. This restricts the light emitted from the light-emitting elements 200 to a narrower angular range, thereby increasing the light output efficiency of the electronic device 30b. In some embodiments, the light-converging element 600 may be uniformly distributed on the barrier wall 300 nearest to the outer frame portion 400a of the back plate 400. In other embodiments, the light-converging element 600 may be distributed in areas corresponding to a light emission angle of 30 to 70 degrees of one of the light-emitting elements, or the light-converging element 600 may have a higher density in areas corresponding to a light emission angle of 30 to 70 degrees of one of the light-emitting elements, but is not limited thereto. In yet other embodiments, the light-converging element 600 may be distributed in 1/2 to 1/4 of the top area of the barrier wall 300 nearest to the outer frame portion 400a of the back plate 400, or the light-converging element 600 may have a higher density in 1/2 to 1/4 of the top area of the barrier wall 300 nearest to the outer frame portion 400a of the back plate 400, but is not limited thereto.

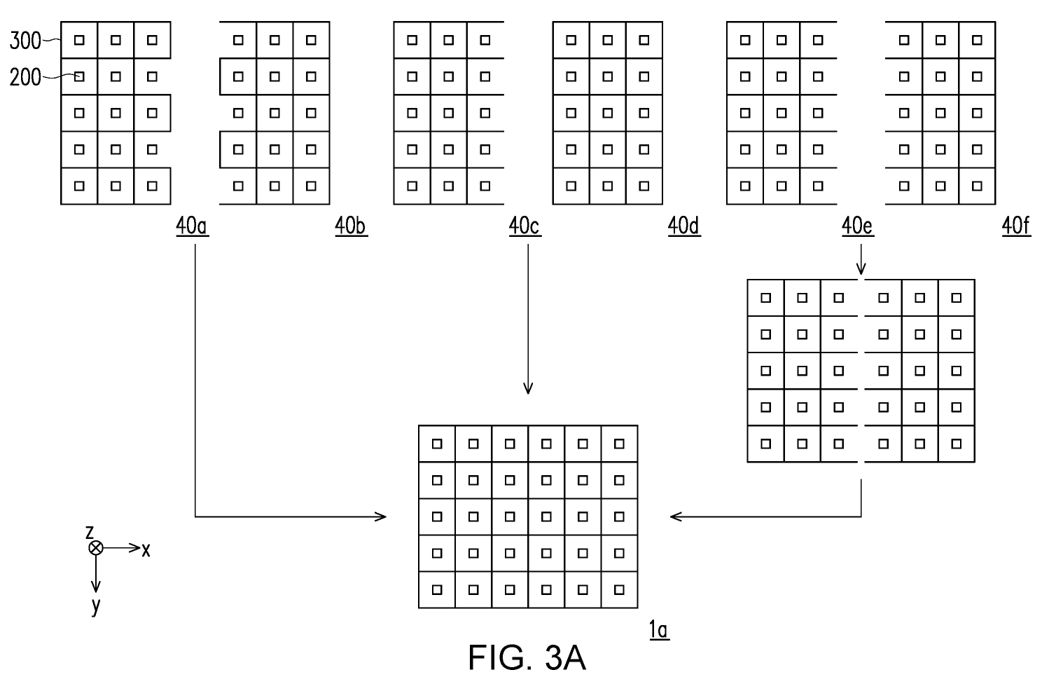

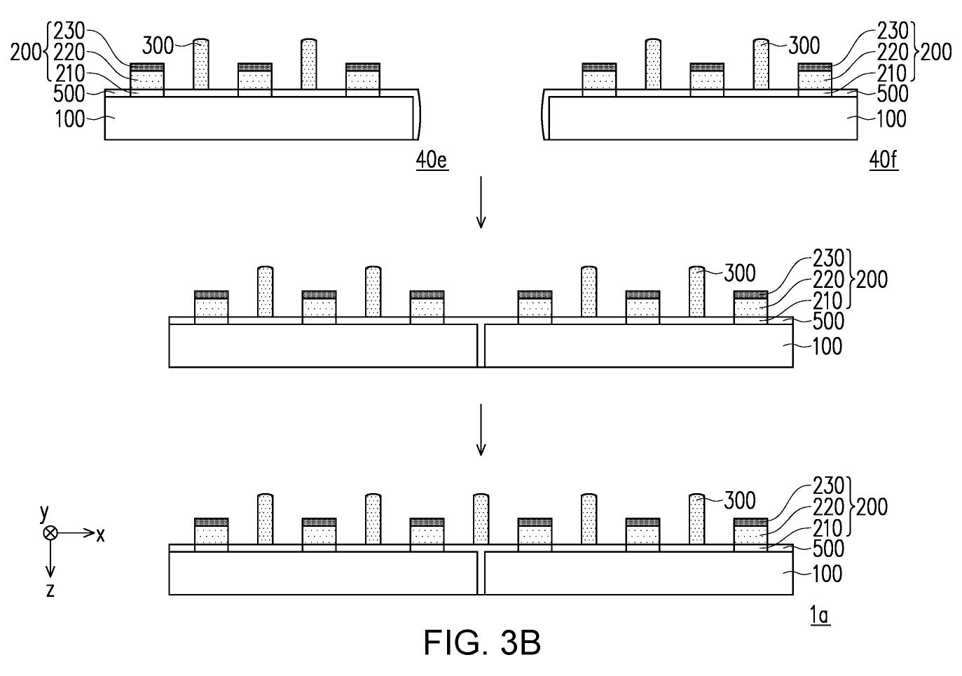

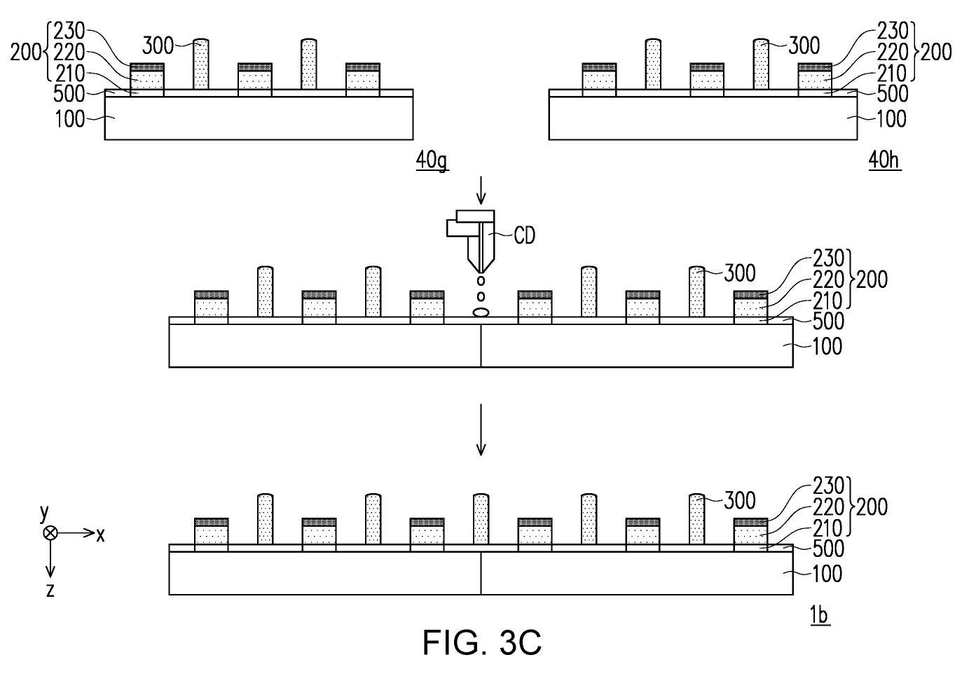

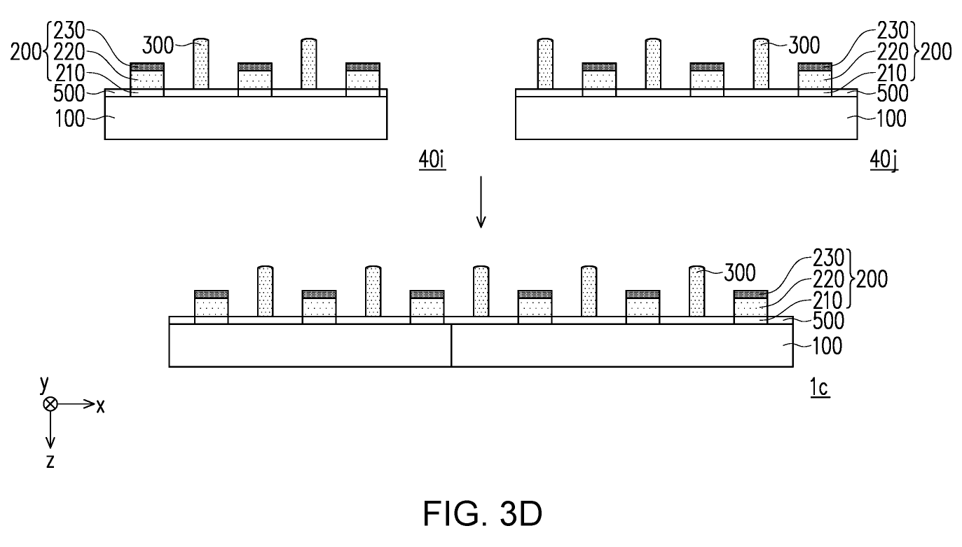

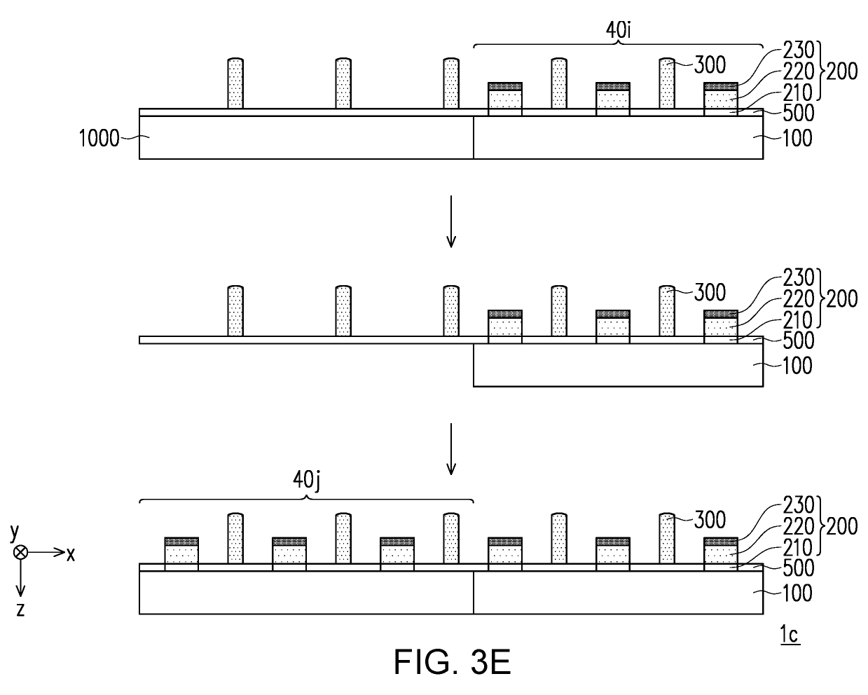

FIG. 3A is a flow chart illustrating a manufacturing method of an electronic device according to the seventh embodiment of the present disclosure. It should be noted that the embodiment of FIG. 3A may adopt the reference numerals and partial content of the embodiment of FIG. 1A, wherein identical or similar numerals are used to denote identical or similar elements, and explanations of identical technical content are omitted.

Referring to FIG. 3A, the electronic device 1a of the present embodiment is a spliced electronic device. A relatively large-sized spliced electronic device may be obtained by splicing a plurality of small-sized electronic devices. Specifically, the electronic device 1a may be obtained, for example, by splicing the electronic device 40a with the electronic device 40b, or by splicing the electronic device 40c with the electronic device 40d, or by splicing the electronic device 40e with the electronic device 40f.

In the present embodiment, the joining edges of various electronic devices are designed. Specifically, at the junction between the electronic device 40a and the electronic device 40b, the barrier walls 300 are positioned on one of the joining edges of the electronic device 40a and the electronic device 40b, thereby mitigating technical issues such as warping, bright lines, and dark lines that might occur at the junction of adjacent electronic devices 40a and 40b. Similarly, at the junction between the electronic device 40c and the electronic device 40d, the barrier walls 300 are positioned on the joining edge of the electronic device 40d, thereby mitigating technical issues such as warping, bright lines, and dark lines that might occur at the junction of adjacent electronic devices 40c and 40d.

For the adjacent electronic devices 40e and 40f, the barrier walls 300 are not positioned at any of the joining edges of the electronic devices 40e and 40f. Instead, after the electronic device 40e is spliced with the electronic device 40f, the barrier walls 300 are formed at the junction of the electronic devices 40e and 40f utilizing spray coating techniques or other suitable processes. This methodology is employed to mitigate technical issues such as warping, bright lines, and dark lines that might occur at the junction of the adjacent electronic devices 40e and 40f.

In greater detail, please refer to FIG. 3B, which illustrates a partial cross-sectional view of an embodiment of the manufacturing method for the electronic device as shown in FIG. 3A. In some embodiments, a reflective layer 500 possessing high reflectivity and adhesive properties may first be formed at the joining edges of the electronic devices 40e and 40f. Subsequent to the joining of the electronic devices 40e and 40f, the barrier walls 300 may be formed at the junction of the electronic devices 40e and 40f utilizing spray coating techniques or other suitable processes. However, the present disclosure is not limited to this particular method.

FIG. 3C is a flow chart illustrating a manufacturing method of an electronic device according to the eighth embodiment of the present disclosure.

Please refer to FIG. 3C. In some other embodiments, the electronic devices 40g and 40h are provided, wherein the barrier walls 300 have not yet been formed in the electronic devices 40g and 40h, and a reflective layer 500 with adhesive properties has not been formed at the joining edges of the electronic devices 40g and 40h. After the electronic devices 40g and 40h are spliced together, the barrier walls 300 are formed within the electronic devices 40g and 40h using spray coating or other suitable processes to form the electronic device 1b. In this embodiment, prior to forming the barrier walls 300, a coating device CD may be used to form a material with high reflectivity and adhesiveness at the seam between the electronic devices 40g and 40h. This material may penetrate the seam, causing the electronic devices 40g and 40h to adhere to each other; however, the present disclosure is not limited to this.

FIG. 3D is a flow chart illustrating a manufacturing method of an electronic device according to the ninth embodiment of the present disclosure.

Please refer to FIG. 3D. In some additional embodiments, the electronic devices 40i and 40j are provided, wherein the electronic devices 40i and 40j may have asymmetrical edge designs due to cutting and other factors. For instance, compared to the joining edge of the electronic device 40j, the light-emitting elements 200 positioned at the edge of the substrate 100 are closer to the joining edge of the electronic device 40i. Based on this configuration, the barrier walls 300 may first be disposed along the joining edge of the electronic device 40j. Subsequently, utilizing the aforementioned coating device, a material with high reflectivity and adhesive properties may be applied to the seam between the electronic devices 40i and 40j. This material may penetrate the seam, thereby adhering the electronic devices 40i and 40j to each other, thus forming the electronic device 1c.

FIG. 3E is a flow chart illustrating a manufacturing method of an electronic device according to the tenth embodiment of the present disclosure.

Please refer to FIG. 3E. In some other embodiments, the electronic device 40i may first be spliced with a provisional light board 1000, wherein the provisional light board 1000 is pre-equipped with a plurality of detachable barrier walls 300 and a reflective layer 500. Subsequently, upon separation of the provisional light board 1000 from the electronic device 40i, the plurality of barrier walls 300 and the reflective layer 500 remain intact and are not removed. Thereafter, the electronic device 40j may be spliced with the electronic device 40i to form the electronic device 1c.

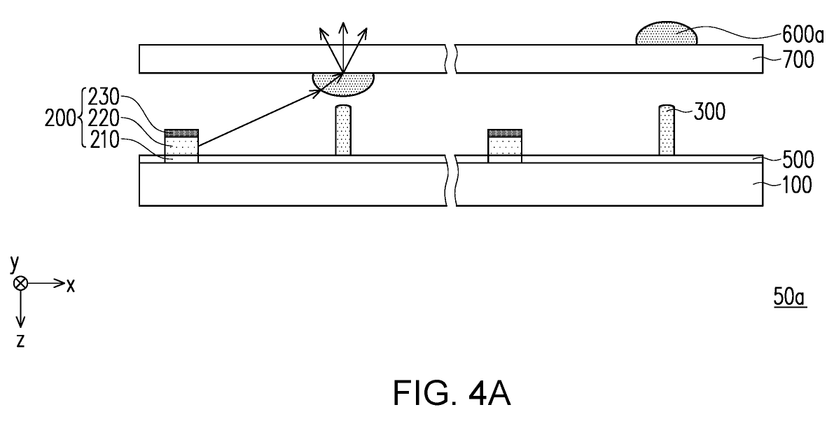

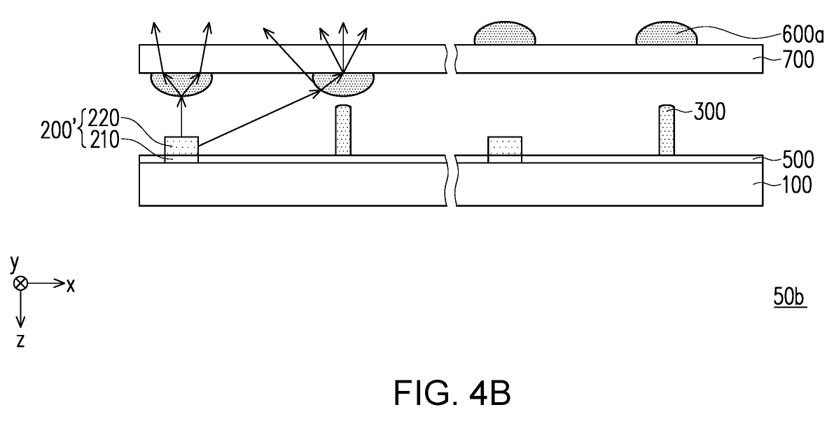

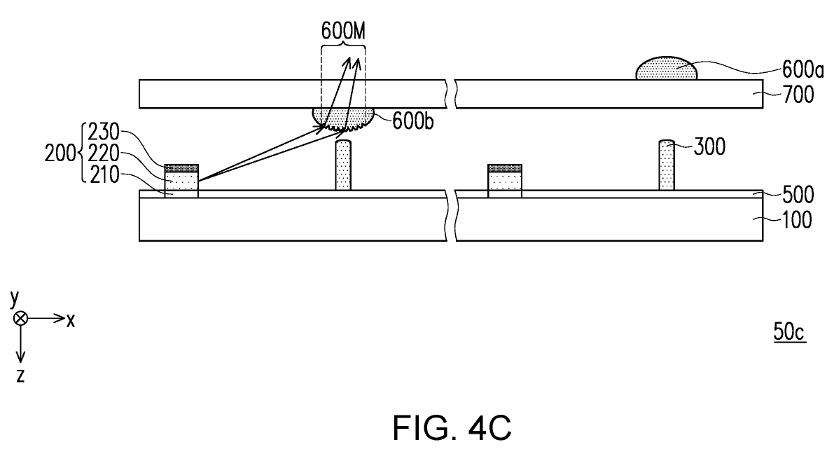

FIG. 4A is a partial cross-sectional view of an electronic device according to the eleventh embodiment of the present disclosure.

Please refer to FIG. 4A. The main difference between the electronic device 50a of this embodiment and the electronic device 10a is that the electronic device 50a further includes a diffusion plate 700 and a light-converging element 600a. The diffusion plate 700, for example, is positioned opposite to the substrate 100 in the top view direction z of the electronic device 50a, and faces one side of the substrate 100 where the light-emitting elements 200 are disposed. The light-converging element 600a, for example, is disposed on the diffusion plate 700. In some embodiments, the light-converging element 600a may include a lens, but the present disclosure is not limited thereto. The light-converging element 600a may, for instance, be disposed on one side of the diffusion plate 700 facing the substrate 100 and/or on one side of the diffusion plate 700 away from the substrate 100. In this embodiment, the light-converging element 600a is correspondingly arranged with the barrier walls 300. Through this design, when light emitted from the light-emitting elements 200 with relatively large angles reach the light-converging element 600a, they may be refracted by the light-converging element 600a and emitted from the diffusion plate 700, thereby reducing the possibility of the light being reflected by the diffusion plate 700 and creating dark areas where the barrier walls 300 are located. In some embodiments, the light-converging element 600a may further include diffusion particles to further enhance the light-converging effect of the light-converging element 600a.

FIG. 4B is a partial cross-sectional view of an electronic device according to the twelfth embodiment of the present disclosure.

Please refer to FIG. 4B. The primary difference between the electronic device 50b in this embodiment and the electronic device 50a is as follows: the light-converging element 600a is additionally correspondingly arranged with the light-emitting elements 200'.

More specifically, in the present embodiment, the plurality of light-emitting elements 200' are five-sided emitting sub-millimeter light-emitting diodes. That is to say, the plurality of light-emitting elements 200' are capable of emitting light in a direction opposite to the top view direction z of the electronic device 50b. By virtue of this design, the possibility of dark areas being produced due to light emitted from the top surface of the light-emitting elements 200' being reflected by the diffusion film 700 is reduced.

FIG. 4C is a partial cross-sectional view of an electronic device according to the thirteenth embodiment of the present disclosure.

Please refer to FIG. 4C. The primary difference between the electronic device 50c in this embodiment and the electronic device 50a is that the light-converging element 600b includes a plurality of microstructures 600M.

Through this design, when light with relatively large angles emitted from the light-emitting elements 200 reach the light-converging element 600b, the possibility of these light being reflected by the diffusion plate 700 and creating dark areas at the location of the barrier walls 300 may be further reduced.

In summary, in the electronic device provided by some embodiments of the present disclosure, the terminal end of at least one of the plurality of first barrier walls is proximate to and spaced apart by a distance from the terminal end of at least one of the plurality of second barrier walls. This configuration allows light emitted from adjacent light-emitting units to mix through the opening between the first barrier wall and the second barrier wall, thereby enhancing the uniformity of light output. Consequently, this arrangement may mitigate the appearance of grid patterns caused by the first barrier wall and/or the second barrier wall during light emission from the electronic device, thus improving the display quality of the electronic device provided by some embodiments of the present disclosure.

Furthermore, in the electronic device provided by other embodiments of this disclosure, the height of the second barrier wall surrounding the outermost column of light-emitting elements is greater than the height of the first barrier wall. Based on this configuration, the plurality of first barrier walls positioned at one edge of the substrate, having a relatively lower height, may enhance the light-mixing effect of the light emitted by the light-emitting elements in the outermost column, thereby improving the display quality of the electronic device provided by other embodiments of this disclosure. Additionally, the number of reflections of light emitted by the light-emitting elements in the outermost column through the plurality of second barrier walls positioned at one edge of the substrate may be increased, which may enhance the light output efficiency of the electronic device provided by other embodiments of this disclosure.

Furthermore, in some embodiments of the electronic device disclosed herein, non-continuous barrier walls are formed through a spraying process. Consequently, the electronic device provided in these embodiments may not require the configuration of light-homogenizing films, high-haze diffusion plates, or similar layered components, thus resulting in comparatively lower manufacturing costs.

WHAT IS CLAIMED IS:

1. An electronic device, comprising:
a substrate;
a plurality of light-emitting elements, arranged in an array on the substrate; and
a plurality of barrier walls, disposed on the substrate and surrounding the plurality of light-emitting elements, wherein the plurality of barrier walls comprises a plurality of first barrier walls extending along a first direction and a plurality of second barrier walls extending along a second direction, and the first direction is perpendicular to the second direction,
wherein in a top view of the electronic device, at least one of the plurality of first barrier walls and at least one of the plurality of second barrier walls surround one of the plurality of light-emitting elements, and a terminal end of the at least one of the plurality of first barrier walls is proximate to and spaced apart by a distance from a terminal end of the at least one of the plurality of second barrier walls.

2. The electronic device according to claim 1, wherein a height of the plurality of barrier walls ranges from 0.2 millimeters to 5 millimeters.

3. The electronic device according to claim 1, wherein a row alignment direction of the plurality of light-emitting elements forms an angle of 40° to 50° with the first direction.

4. The electronic device according to claim 1, wherein a column alignment direction of the plurality of light-emitting elements forms an angle of 40° to 50° with the second direction.

5. The electronic device according to claim 1, wherein a row alignment direction of the plurality of light-emitting elements is parallel to the first direction.

6. The electronic device according to claim 1, wherein a column alignment direction of the plurality of light-emitting elements is parallel to the second direction.

7. The electronic device according to claim 1, further comprising a back plate, wherein the back plate is positioned on one side of the substrate away from the plurality of light-emitting elements, wherein a height of a barrier wall nearest to an outer frame portion of the back plate is greater than a height of the other barrier walls.

8. The electronic device according to claim 7, wherein a distance between the barrier wall nearest to the outer frame portion of the back plate and the one of the plurality of light-emitting elements is equal to a distance between the other barrier walls and another of the plurality of light-emitting elements.

9. The electronic device according to claim 7, wherein a distance between the barrier wall nearest to the outer frame portion of the back plate and the one of the plurality of light-emitting elements is different from a distance between the other barrier walls and another of the plurality of light-emitting elements.

10. The electronic device according to claim 9, wherein the distance between the barrier wall nearest to the outer frame portion of the back plate and the one of the plurality of light-emitting elements is greater than the distance between the other barrier walls and the another of the plurality of light-emitting elements.

11. The electronic device according to claim 1, further comprising a back plate and a light-converging element, wherein the back plate is disposed on one side of the substrate away from the plurality of light-emitting elements, and the light-converging element is disposed on a barrier wall nearest to an outer frame portion of the back plate.

12. The electronic device according to claim 11, wherein the light-converging element is uniformly distributed on the barrier wall nearest to the outer frame portion of the back plate.

13. The electronic device according to claim 11, wherein the light-converging element is distributed in an area corresponding to a light emission angle of 30 to 70 degrees of the one of the plurality of light-emitting elements.

14. The electronic device according to claim 11, wherein the light-converging element has a higher density in an area corresponding to a light emission angle of 30 to 70 degrees of the one of the plurality of light-emitting elements.

15. The electronic device according to claim 11, wherein the light-converging element is distributed in 1/2 to 1/4 of a top area of the barrier wall nearest to the outer frame portion of the back plate.

16. The electronic device according to claim 11, wherein the light-converging element has a higher density in 1/2 to 1/4 of a top area of the barrier wall nearest to the outer frame portion of the back plate.

17. An electronic device, comprising:
a substrate;
a plurality of light-emitting elements, arranged in an array on the substrate; and
a plurality of barrier walls, disposed on the substrate and surrounding the plurality of light-emitting elements, wherein the plurality of barrier walls comprises a plurality of first barrier walls extending along a first direction and a plurality of second barrier walls extending along a second direction, and the first direction is perpendicular to the second direction,
wherein in a top view of the electronic device, at least one of the plurality of first barrier walls and at least one of the plurality of second barrier walls surround one of the plurality of light-emitting elements, and the at least one of the plurality of first barrier walls is connected to the at least one of the plurality of second barrier walls, and the at least one of the plurality of first barrier walls has an opening.

18. The electronic device according to claim 17, wherein a height of the plurality of barrier walls ranges from 0.2 millimeters to 5 millimeters.

19. The electronic device according to claim 17, wherein the one of the plurality of light-emitting elements is situated in an outermost column of the plurality of light-emitting elements.

20. The electronic device according to claim 19, wherein a height of a second barrier wall surrounding the one of the plurality of light-emitting elements located in the outermost column of the plurality of light-emitting elements is greater than a height of a first barrier wall.
